(19) United States
(12) Patent Application Publication
(10) Pub. No.: US 2026/0146786 A1
(43) Pub. Date: May 28, 2026

(54) LOW NOISE LIQUID HELIUM RELIQUIFYING CIRCULATION APPARATUS

(71) Applicant: Korea Research Institute of Standards and Science, Daejeon (KR)

(72) Inventors: Kwon-Kyu YU, Daejeon (KR); Yong-Ho LEE, Daejeon (KR); Jin-Mok KIM, Daejeon (KR); Bo-Kyung KIM, Daejeon (KR)

(21) Appl. No.: 19/422,511

(22) Filed: Dec. 17, 2025

Related U.S. Application Data
(63) Continuation of application No. PCT/KR2024/011946, filed on Aug. 12, 2024.

(30) Foreign Application Priority Data
Aug. 18, 2023 (KR) 10-2023-0108156

(51) Int. Cl. F25J 1/02; F25J 1/00

(52) U.S. Cl. CPC F25J 1/0225; F25J 1/0007; F25J 1/0262; F25J 2270/912; F25J 2290/30

(57) ABSTRACT

A liquid helium reliquefying circulation apparatus according to an embodiment of the present disclosure includes a pulse tube cryocooler comprising a cold head, a first stage heat exchanger, and a second stage heat exchanger; an upper inner chamber disposed to surround a first stage regenerator disposed on the first stage heat exchanger; a lower inner chamber disposed to surround the second stage heat exchanger and a second stage regenerator disposed on the second stage heat exchanger; and a cryocooler inner pipe, connected to a lower plate of the lower inner chamber, formed of metal, transporting liquid helium, and having flexibility.

This application is a continuation of and claims priority to PCT/KR2024/011946 filed on Aug. 12, 2024, which claims priority to Korea Patent Application No. 10-2023-0108156 filed on Aug. 18, 2023, the entireties of which are both hereby incorporated by reference.

### TECHNICAL FIELD

The present disclosure relates to a liquid helium reliquefying circulation apparatus, and more particularly, to a liquid helium reliquefying circulation apparatus with suppressed magnetic noise and electrical nose.

### BACKGROUND ART

A superconducting quantum interference device (SQUID) for ultra-minute micromagnetic field measurement is used in a wide range of fields, including medical diagnosis, resource exploration, and fundamental science. A low-temperature SQUID (Low Tc SQUID) sensor is manufactured using Nb/AlOx/Nb multilayer structure and a micro-pattern structure, and an antenna for detecting a magnetic field detection may be used by winding NbTi in a desired direction. Niobium (Nb) used in a SQUID element exhibits superconducting behavior at about 9.2 K, and a NbTi alloy that is a signal detection coil material exhibits superconducting behavior at 10 K. Accordingly, by using liquid helium having a liquefaction temperature of 4.2 K, a measurement apparatus using a SQUID is cooled to operate.

A SQUID sensor should measure weak magnetic signals, which are millions to billions of times smaller than external environmental noise (earth's magnetic field; 50 μT), to block environmental noise. Josephson junction (Nb/AlOx/Nb) of the SQUID sensor significantly changes in characteristics due to electromagnetic wave noise, so that a measurement system operates unstably due to external electromagnetic wave noise. Accordingly, a SQUID-based magnetic measurement device should be installed and operate within a magnetically shielded room (MSR), capable of shielding both the earth's magnetic field and electromagnetic waves.

Liquid helium, a cryogenic temperature refrigerant used for system operation, is not only significantly expensive, but also significantly difficult in continuously operating a measurement apparatus. To address these issues, a method for reliquefying and circulating helium gas evaporated from a liquid helium storage container (or Dewar) (U.S. Pat No. 8,375,742 B2) is used or a method for directly cooling a system with a cryocooler (WO 2016/036078 A1) is being used.

A helium reliquefying circulation apparatus for biomagnetic measurement affects an evaporation rate of a Dewar and cooling characteristics of a SQUID sensor mounted in a vacuum layer. Accordingly, a direction of low-temperature helium gas circulation needs to controlled to significantly use waste heat from the helium gas evaporated from the Dewar. In addition, not only the direction but also an amount of circulating gas needs to be controlled to increase a reliquefying rate of the circulated helium gas.

A helium reliquefying circulation apparatus includes a chamber housing a cryocooler head for reliquefaction, a refrigerant transport pipe (or a refrigerant transport tube) for transporting liquid helium that is a refrigerant for delivering reliquefied liquid helium to a Dewar, and a return gas line through which low-temperature gas evaporated from the Dewar is delivered to the chamber housing a cryocooler.

### DISCLOSURE OF THE INVENTION

### Technical Problem

The present disclosure aims to provide a liquid helium reliquefying circulation apparatus that minimizes electromagnetic noise.

This is achieved by using non-metallic materials (such as GFRP or CFRP) for both the inner chamber and the liquid helium transport pipe, thereby electrically isolating the inside and outside of the magnetically shielded room.

This innovation significantly reduces electromagnetic noise, improves the signal-to-noise ratio, and ensures continuous 24-hour operation of micromagnetic field measurement systems like magnetoencephalography and magnetocardiography.

Additionally, the apparatus integrates a liquid helium transport pipe and an evaporation gas recovery line to streamline the structure.

This integration facilitates efficient attitude control of the magnetic measurement apparatus and enhances the cooling efficiency of the cryocooler by incorporating a heat shield within the inner chamber. Furthermore, the use of a flexible liquid helium transport pipe reduces vibration noise, contributing to the system's overall stability and effectiveness.

### Technical Solution

A liquid helium reliquefying circulation apparatus according to an embodiment of the present disclosure includes a pulse tube cryocooler comprising a cold head, a first stage heat exchanger, and a second stage heat exchanger; an upper inner chamber disposed to surround a first stage regenerator disposed on the first stage heat exchanger; a lower inner chamber disposed to surround the second stage heat exchanger and a second stage regenerator disposed on the second stage heat exchanger; and a cryocooler inner pipe, connected to a lower plate of the lower inner chamber, formed of metal, transporting liquid helium, and having flexibility.

In an embodiment, the upper inner chamber and the lower inner chamber may be formed of glass fiber reinforced plastic (GFRP).

In an embodiment, the liquid helium reliquefying circulation apparatus further includes a transport pipe assembly. The transport pipe assembly comprises an outer transport pipe and an inner transport pipe disposed inside the outer transport pipe. The transport pipe assembly includes an insulation portion to reduce a magnetic and electric noise.

In an embodiment, the inner transport pipe comprises a flexible section to reduce vibration noise.

In an embodiment, the liquid helium reliquefying circulation apparatus further includes at least one a thermal anchor coupled to the first stage heat exchanger; a heat shield disposed coupled to the thermal anchor and to disposed to surround the lower inner chamber; a first flange spaced apart the thermal anchor; a second flange disposed on the first flange and coupled to a lower surface of the cold head; and a superinsulator layer disposed between the heat shield and an outer chamber. The first flange and the second flange are connected by a bellows.

In an embodiment, the liquid helium reliquefying circulation apparatus further includes a transport pipe assembly and a return gas line. The transport pipe assembly and the return gas line are integrated.

In an embodiment, the upper inner chamber and the lower inner chamber are made of metal.

In an embodiment, the liquid helium reliquefying circulation apparatus further includes a transport pipe assembly. The transport pipe assembly comprises an outer transport pipe; and an inner transport pipe situated inside the outer transport pipe. The inner transport pipe comprises an inner insertion portion that is inserted into a magnetic field measuring apparatus; an inner elbow portion connected to the inner insertion portion; and an inner flexible portion that connects the inner elbow portion to the cryocooler inner pipe.

In an embodiment, the outer transport pipe comprises, an outer insertion portion that is inserted into the magnetic field measurement apparatus; an outer elbow portion connected to the outer insertion portion; and an outer flexible portion that connects the outer elbow portion to a cryocooler outer pipe. The outer flexible portion of the outer transport pipe is made of PTFE bellows, providing the necessary flexibility.

In an embodiment, the inner flexible portion of the inner transport pipe comprise a metal inner bellows. The inner flexible portion of the inner transport pipe comprises an insulating inner union. The insulating inner union connects the cryocooler inner pipe and the metal inner bellows. The insulating inner union comprises: a first nipple that is screw-coupled to a sleeve of the cryocooler inner pipe and a sleeve of the metal inner bellows; and a second nipple is screw-coupled to the first nipple and connects to the sleeves of both the cryocooler inner pipe and the metal inner bellows.

In an embodiment, both the inner and outer elbow portions are bent at 110 degrees and are formed of metal, ensuring structural integrity and proper alignment. The outer and inner insertion portions are designed with a double-tube structure. The outer insertion portion consists of an inner and outer tube. The inner insertion portion, made from insulating material, includes an inner and outer tube. The outer tube of the inner insertion portion is coupled to the double-tube structure of the outer insertion portion, thereby sealing the inner insertion portion effectively.

In an embodiment, the liquid helium reliquefying circulation apparatus further includes a return gas line. The transport pipe assembly incorporates the return gas line inside the outer transport pipe. The return gas line branches off from the outer insertion portion. The return gas line facilitates a circulation of helium gas to enhance its efficiency.

In an embodiment, the liquid helium reliquefying circulation apparatus further includes a transport pipe assembly. The transport pipe assembly comprises inner and outer connection portions that connect the respective ends of the cryocooler inner and outer pipes. The inner and outer connection portions are designed to be sealed to each other, ensuring no leakage and maintaining the integrity. The outer connection portion connects the outer transport pipe to an outer intermediate pipe. The inner connection portion connects the cryocooler outer pipe to an inner intermediate pipe.

A liquid helium reliquefying circulation apparatus according to an embodiment of the present disclosure includes a pulse tube cryocooler including a cold head, a first stage heat exchanger, and a second stage heat exchanger; a thermal anchor coupled to the first stage heat exchanger; an upper inner chamber formed of a dielectric material, screw-coupled to the thermal anchor, coupled to a first flange spaced apart from the thermal anchor, and disposed to surround a first stage regenerator disposed on the first stage heat exchanger; a lower inter chamber formed of a dielectric material and disposed to surround the second stage heat exchanger and a second stage regenerator disposed on the second stage heat exchanger; a heat shield disposed coupled to the thermal anchor and to disposed to surround the lower inner chamber; and a cryocooler inner pipe connected to a lower plate of the lower inner chamber, formed of metal transporting liquid helium, and having flexibility.

In an embodiment, the liquid helium reliquefying circulation apparatus may further include: a second flange disposed on the first flange and coupled to a lower surface of the cold head. The first flange and the second flange may be coupled by a bellows, and the liquid helium reliquefying circulation apparatus may further include an outer chamber made of metal, coupled to the first flange and disposed to surround the heat shield.

In an embodiment, the liquid helium reliquefying circulation apparatus may further include: a superinsulator layer disposed between the heat shield and the outer chamber.

In an embodiment, the upper inner chamber and the lower inner chamber may be formed of glass fiber reinforced plastic.

In an embodiment, the lower plate of the lower inner chamber may have a through-hole. The liquid helium reliquefying circulation apparatus further include a connection member connecting the cryocooler inner pipe and the lower plate. The connection member may include: a conductive nipple inserted into the through-hole to be screw-coupled; a socket comprising a flange coupled to a lower surface of the lower plate of the lower inner chamber and screw-coupled to the conductive nipple; and an insulating nipple screw-coupled to an inner side surface of the conductive nipple and screw-coupled to an upper surface of the lower plate of the lower inner chamber. One end of the cryocooler flexible pipe is continuously connected to the conductive nipple.

In an embodiment, the liquid helium reliquefying circulation apparatus may further include a cryocooler outer pipe coupled to a lower end portion of the outer chamber and coupled to an outer transport pipe, and the cryocooler inner pipe may be disposed in the cryocooler outer pipe.

In an embodiment, the liquid helium reliquefying circulation apparatus may further include a transport pipe for transporting the liquid helium to a magnetic field measurement apparatus. The transport pipe may include an outer transport pipe and an inner transport pipe disposed inside the outer transport pipe. The inner transport pipe may include: an inner insertion portion inserted into the magnetic field measurement apparatus; an inner elbow portion continuously connected to the insertion portion; and an inner flexible portion connecting the inner elbow portion and the cryocooler inner pipe. The outer transport pipe may include: an outer insertion portion inserted into the magnetic field measurement apparatus; an outer elbow portion continuously connected to the outer insertion portion; and an outer flexible portion connecting the outer elbow portion and the liquid helium outer pipe. The outer flexible portion of the outer transport pipe may include a flexible portion formed of an insulating material.

A liquid helium transport pipe according to an example embodiment transports liquid helium of a liquid helium reliquefying circulation apparatus to a magnetic field measurement apparatus. The liquid helium transport pipe includes: an outer transport pipe and an inner transport pipe disposed inside the outer transport pipe. The inner transport pipe may include: an inner insertion portion inserted into the magnetic field measurement apparatus; an inner elbow portion continuously connected to the insertion portion; and an inner flexible portion connecting the inner elbow portion and a cryocooler inner pipe, formed of metal, of the liquid helium reliquefying circulation apparatus. The outer transport pipe may include an outer insertion portion inserted into the magnetic field measurement apparatus; an outer elbow portion continuously connected to the outer insertion portion; and an outer flexible portion connecting the outer elbow portion and a cryocooler outer pipe, formed of metal, of the liquid helium reliquefying circulation apparatus. The outer flexible portion of the outer transport pipe may include a flexible portion formed of an insulating material.

In an embodiment, the outer flexible portion of the outer transport pipe may be a bellows formed of PTFE.

In an embodiment, the inner flexible portion may be a bellows formed of metal, and the inner flexible portion may include an inner bellows formed of metal; and an insulating inner union connecting the cryocooler inner pipe, formed of metal, of the refrigerant reliquefying apparatus and the inner bellows.

In an embodiment, the insulating inner union may include a first nipple screw-coupled to a sleeve of the inner transport pipe and screw-coupled to a sleeve of the inner bellows; and a second nipple screw-coupled to the first nipple and screw-coupled to the sleeve of the inner transport pipe and the sleeve of the inner bellows.

In an embodiment, the inner elbow portion may be bent 110 degrees and formed of metal, and the outer elbow portion may be bent 110 degrees and formed of metal.

In an embodiment, the outer insertion portion may have a double-tube structure including an inner tube and an outer tube, and the inner insertion portion may be formed of an insulating material and have a double-tube structure including an inner tube and an outer tube.

In an embodiment, the outer tube of the double-tube structure of the inner insertion portion may be coupled to the double-tube structure of the outer insertion portion to seal the inner insertion portion.

A liquid helium reliquefying circulation apparatus according to an embodiment of the present disclosure includes: a pulse tube cryocooler including a cold head, a first stage heat exchanger, and a second stage heat exchanger; a thermal anchor coupled to the first stage heat exchanger; an upper inner chamber formed of metal, screw-coupled to the thermal anchor, coupled to a first flange spaced apart from the thermal anchor, and disposed to surround a first stage regenerator disposed on the first stage heat exchanger; a lower inter chamber formed of metal and disposed to surround the second stage heat exchanger and a second stage regenerator disposed on the second stage heat exchanger; a heat shield disposed coupled to the thermal anchor and to disposed to surround the lower inner chamber; and a cryocooler inner pipe connected to a lower plate of the lower inner chamber, formed of metal transporting liquid helium, and having flexibility. The liquid helium reliquefying circulation apparatus may further include a transport pipe for transporting the liquid helium to a magnetic field measurement apparatus. The transport pipe may include an outer transport pipe and an inner transport pipe disposed inside the outer transport pipe. The inner transport pipe may include: an inner insertion portion inserted into the magnetic field measurement apparatus; an inner elbow portion continuously connected to the insertion portion; and an inner flexible portion connecting the inner elbow portion and the cryocooler inner pipe. The outer transport pipe may include: an outer insertion portion inserted into the magnetic field measurement apparatus; an outer elbow portion continuously connected to the outer insertion portion; and an outer flexible portion connecting the outer elbow portion and the liquid helium outer pipe. The outer flexible portion of the outer transport pipe may include a flexible portion formed of an insulating material.

A liquid helium reliquefying circulation apparatus according to an embodiment of the present disclosure includes: a pulse tube cryocooler including a cold head, a first stage heat exchanger, and a second stage heat exchanger; a thermal anchor coupled to the first stage heat exchanger; an upper inner chamber formed of metal, screw-coupled to the thermal anchor, coupled to a first flange spaced apart from the thermal anchor, and disposed to surround a first stage regenerator disposed on the first stage heat exchanger; a lower inter chamber formed of metal and disposed to surround the second stage heat exchanger and a second stage regenerator disposed on the second stage heat exchanger; a heat shield disposed coupled to the thermal anchor and to disposed to surround the lower inner chamber; and a cryocooler inner pipe connected to a lower plate of the lower inner chamber, formed of metal transporting liquid helium, and having flexibility. The liquid helium reliquefying circulation apparatus may further include a transport pipe for transporting the liquid helium to a magnetic field measurement apparatus. The transport pipe may include: an outer transport pipe; an inner transport pipe disposed inside the outer transport pipe; and an outer connection portion connecting one end of the outer transport pipe and one end of the inner transport pipe to each other.

In an embodiment, the liquid helium reliquefying circulation apparatus may further include: a cryocooler inner pipe having one end connected to the inner chamber; a cryocooler outer pipe having one end connected to the outer chamber; and an inner connection portion connecting the other end of the cryocooler outer pipe and the other end of the cryocooler inner pipe to each other. The outer connection portion and the inner connection portion may be sealed to each other.

A liquid helium transport pipe according to an embodiment of the present disclosure transports liquid helium of a liquid helium reliquefying circulation apparatus to a magnetic field measurement apparatus. The transport pipe may include an inner transport pipe disposed inside the outer transport pipe; and an outer connection portion connecting one end of the outer transport pipe and one end of the inner transport pipe to each other.

In an embodiment, the liquid helium reliquefying circulation apparatus may include: a cryocooler inner pipe having one end connected to the inner chamber; a cryocooler outer pipe having one end connected to the outer chamber; and an inner connection portion connecting the other end of the cryocooler outer pipe and the other end of the cryocooler inner pipe to each other. The outer connection portion and the inner connection portion may be sealed to each other.

In an embodiment, the outer connection portion may include: a first outer connection portion connecting the outer transport pipe and an outer intermediate pipe; and a second outer connection portion connecting the intermediate pipe and the outer transport pipe. The inner connection portion may include: a first inner connection portion connecting the cryocooler outer pipe and an inner intermediate pipe; and a second inner connection portion connecting the inner intermediate pipe and the cryocooler inner pipe. The first outer connection portion may be coupled to the first inner connection portion to be sealed, and the second outer connection portion may be coupled to the second inner connection portion to be sealed.

In an embodiment, the outer transport pipe may further include an outer bellows portion and an outer elbow portion, both formed of metal, and the inner transport pipe may further include an inner bellows formed of metal.

In an embodiment, the inner transport pipe may be screw-coupled to the inner bellows portion, and the inner bellows portion may pass through the outer elbow portion.

In an embodiment, the outer transport pipe may further include an outer insertion portion inserted into the magnetic field measurement apparatus, and the inner transport pipe may further include an inner insertion portion inserted into the magnetic field measurement apparatus.

In an embodiment, the outer elbow portion may be bent 110 degrees and formed of metal.

In an embodiment, the outer insertion portion may be formed of metal and have a double-tube structure including an inner tube and an outer tube, and the inner insertion portion may be formed of an insulating material and have a double-tube structure including an inner tube and an outer tube.

In an embodiment, the outer tube of the double-tube structure of the inner insertion portion may be coupled to the double-tube structure of the outer insertion portion to seal the inner insertion portion.

A liquid helium reliquefying circulation apparatus according to an embodiment of the present disclosure includes: a pulse tube cryocooler including a cold head, a first stage heat exchanger, and a second stage heat exchanger; a thermal anchor coupled to the first stage heat exchanger; an upper inner chamber formed of metal, screw-coupled to the thermal anchor, coupled to a first flange spaced apart from the thermal anchor, and disposed to surround a first stage regenerator disposed on the first stage heat exchanger; a lower inter chamber formed of metal and disposed to surround the second stage heat exchanger and a second stage regenerator disposed on the second stage heat exchanger; a heat shield disposed coupled to the thermal anchor and to disposed to surround the lower inner chamber; and a cryocooler inner pipe connected to a lower plate of the lower inner chamber, formed of metal transporting liquid helium, and having flexibility. The liquid helium reliquefying circulation apparatus may further include a transport pipe for transporting the liquid helium to a magnetic field measurement apparatus. The transport pipe may include an outer transport pipe and an inner transport pipe disposed inside the outer transport pipe, and the transport pipe may further include a return gas line disposed inside the outer transport pipe and branching off from the outer insertion portion.

A liquid helium transport pipe according to an embodiment of the present disclosure transports liquid helium of a liquid helium reliquefying circulation apparatus to a magnetic field measurement apparatus. The liquid helium transport pipe may include an outer transport pipe and an inner transport pipe disposed inside the outer transport pipe. The inner transport pipe may include: an inner insertion portion inserted into the magnetic field measurement apparatus; and an inner flexible portion connecting the inner elbow portion and a cryocooler inner pipe, formed of metal, of the refrigerant reliquefying apparatus. The outer transport pipe may include: an outer insertion portion inserted into the magnetic field measurement apparatus; an outer elbow portion continuously connected to the outer insertion portion; and an outer flexible portion connecting the outer elbow portion and a cryocooler inner pipe, formed of metal, of the liquid helium reliquefying circulation apparatus. The liquid helium transport pipe may further include a return gas line disposed inside the outer transport pipe and branching off from the outer insertion portion.

The liquid helium transport pipe may further include an outer coupling portion connected to the outer flexible portion and formed of an insulating material. The liquid helium transport pipe may further include an inner coupling portion connected to the inner flexible portion and formed of an insulating material.

### Advantageous Effects

The present disclosure offers several key benefits that enhance the functionality and reliability of micromagnetic field measurement systems. One of the primary advantages is the significant reduction of electromagnetic noise. By utilizing non-metallic materials, such as Glass Fiber Reinforced Plastic (GFRP) or Poly Tetra Fluoro Ethylene (PTFE), for constructing the inner chamber and helium transport pipe, the system achieves effective electrical isolation between the inside and outside of the magnetically shielded room. This isolation is crucial in minimizing the electromagnetic noise that can interfere with sensitive biomagnetic measurements.

Another critical effect is the improved signal-to-noise ratio. The isolation of electromagnetic noise influx between the inside and outside of the magnetically shielded room significantly enhances this ratio. This improvement leads to greater accuracy and reliability in micromagnetic field measurement systems, such as magnetoencephalography (MEG) and magnetocardiography (MCG), which are used to detect and analyze extremely weak magnetic fields generated by neural or cardiac activity.

The use of a flexible liquid helium transport pipe also contributes to the reduction of vibration noise. The flexibility of this pipe minimizes vibrations during the transport of helium, thereby increasing the overall stability of the system. This reduction in vibration noise is vital for maintaining the precision of measurements in a highly sensitive environment.

Furthermore, the improved design characteristics of the system allow for continuous operation, enabling micromagnetic field measurement systems to function seamlessly for 24 hours. This capability is particularly beneficial in research and clinical settings, where consistent and uninterrupted data collection is essential. The continuous operation not only enhances the utility of these systems but also ensures that they can be relied upon for extended periods without the need for frequent maintenance or adjustments.

Overall, the innovations presented in this disclosure significantly advance the performance of micromagnetic field measurement systems by reducing electromagnetic and vibration noise, improving signal-to-noise ratios, and supporting continuous operation. These enhancements make the systems more effective and reliable for both research and clinical applications.

### BRIEF DESCRIPTION OF THE DRAWINGS

FIG. 1 is a perspective view illustrating a magnetic field measurement system according to an embodiment of the present disclosure.

FIG. 2 is a conceptual diagram illustrating a magnetic field measurement system according to an embodiment of the present disclosure.

FIG. 3 is a conceptual diagram illustrating a liquid helium reliquefying circulation apparatus and a refrigerant transport pipe of FIG. 2.

FIG. 4 is an enlarged view illustrating a connection portion of the liquid helium reliquefying circulation apparatus and the refrigerant transport pipe of FIG. 3.

FIG. 5 is a conceptual diagram illustrating the refrigerant transport pipe of FIG. 3.

FIG. 6 is a conceptual diagram illustrating a liquid helium reliquefying circulation apparatus according to another embodiment of the present disclosure.

FIG. 7 is an enlarged view illustrating a connection part of the liquid helium reliquefying circulation apparatus and the refrigerant transport pipe of FIG. 6.

FIG. 8 is a conceptual diagram illustrating the refrigerant transport pipe of FIG. 6.

FIG. 9 is a conceptual diagram illustrating a liquid helium reliquefying circulation apparatus according to another embodiment of the present disclosure.

FIG. 10 is an enlarged view illustrating a refrigerant transport pipe and connection portion of FIG. 9.

FIG. 11 is a conceptual diagram illustrating a liquid helium reliquefying circulation apparatus according to another embodiment of the present disclosure.

FIG. 12 is a drawing illustrating a refrigerant transport pipe of FIG. 11.

FIG. 13 is an enlarged view illustrating an elbow portion of the refrigerant transport pipe of FIG. 12.

FIG. 14 is a frequency spectrum diagram illustrating noise of a liquid helium reliquefying circulation apparatus according to an embodiment of the present disclosure and noise of a conventional liquid helium reliquefying apparatus.

FIG. 15 is a diagram illustrating operating characteristics of a liquid helium reliquefying apparatus according to an embodiment of the present disclosure.

FIG. 16 is a diagram illustrating a helium level of a Dewar by a liquid helium reliquefying apparatus according to an embodiment of the present disclosure.

### MODE FOR CARRYING OUT THE INVENTION

In a liquid helium reliquefying circulation apparatus according to an embodiment of the present disclosure, a reliquefying chamber and the liquid helium transport pipe (a refrigerant transport pipe) are integrated into a single unit. Specifically, the reliquefying chamber is divided into an inner tube and an outer tube. To block heat transfer (radiation, convection, or conduction) from the outside, the inner tube and the outer tube are separated by a vacuum layer, and a multilayer thermal insulation material is installed at the vacuum layer.

The inner tube of the reliquefying chamber is manufactured by connecting an inner chamber, housing a cryocooler, and a liquid helium transport pipe using low-temperature welding because thermal deformation of a material arises from a significant temperature change.

A cryocooler cold head (CryoMech; PT-410), housed in the reliquefying chamber, generates high magnetic noise due to an operating frequency of 1.4 Hz. Therefore, the cryocooler cold head is installed outside a magnetically shielded room. To transport liquid helium to a Dewar (a refrigerant storage container), a through-hole or slit is formed in the magnetically shielded room and the liquid helium transport pipe is connected to the Dewar through the through-hole or slit.

A reliquefier according to the related art inserts an electrical insulating material between a motor valve and a cold head to internally block electromagnetic noise. However, such a structure fails to block electrical noise and magnetic noise generated from the cold head. Accordingly, a method of blocking electrical noise and magnetic noise generated from a cold head is required.

A pulse tube cryocooler has lower inherent vibration and magnetic noise than other cooling systems. A liquid helium reliquefying circulation apparatus includes a reliquefying chamber and a cold head mounted at the reliquefying chamber.

Helium gas evaporated from a SQUID Dewar enters a reliquefying chamber through a return gas line and a liquid helium transport pipe. The return gas line is formed as a vacuum insulated tube such that a helium gas temperature is maintained in the return gas line as low as possible to slightly increase a liquefaction rate of the cryocooler. The return gas line of the double-tube structure helps prevent icing on an upper plate of the SQUID Dewar. When a single tube is used as the return gas line, severe icing forms on the upper plate of the SQUID Dewar to increase the likelihood of vacuum leakage.

When the liquid helium transport pipe is formed of double-walled stainless steel, the stainless steel is originally a material having low magnetic properties, but the magnetic properties are improved by welding end portions of the stainless steel. The liquid helium transport pipe is conductive, and the liquid helium transport pipe generates magnetic noise and electrical noise inside the measuring device. The inner tube of the reliquefying chamber may be formed of a dielectric material to reduce such magnetic noise and electrical noise. Alternatively, an insulating portion is inserted into the liquid helium transport pipe to reduce magnetic noise and electrical noise.

Biomagnetic signals generated in brain, heart, muscles, spinal cord, or the like, of adults, children, and fetuses are significantly weak and are measured using a SQUID sensor that may measure ultra-minute magnetic signals. A subject and a measuring system are separated from an external environment using a high-performance magnetically shielded room to ensure accurate signal analysis and diagnosis.

However, a currently used liquid helium reliquefying circulation apparatus uses an industrial system, formed of general metal (stainless steel), and introduces external electromagnetic (RF) noise and geomagnetic (DC magnetic field) noise into a magnetically shielded room. Such external noise introduction reduces a signal-to-noise ratio of a minute biomagnetic signal and acts as a factor deteriorating operational stability of the SQUID sensor.

The present disclosure provides a shape and a manufacturing method of a liquid helium reliquefying circulation apparatus, capable of electrically and magnetically isolating the inside and outside of a magnetically shielded room.

A method of periodically replenishing liquid helium requires high cost of purchasing liquid helium and an effort to fill the helium. Recently, it is significantly difficult to purchase liquid helium, and the price thereof has increased significantly. Disadvantageously, a SQUID device cannot be used during the time it takes to fill and stabilize the helium.

A technology developed to address the above issues is a method of reliquefying evaporated gas of a low-temperature refrigerant and then recirculating the evaporated gas to a low-temperature refrigerant storage container. However, recirculation apparatuses currently in use have been developed to focus on increasing liquefaction efficiency. A low-temperature refrigerant recirculation apparatus, developed in the past and applied to measurement of biomagnetic signals, obtains signals by stopping a refrigerant reliquefier and then operating a measuring system due to electromagnetic noise generated from reliquefier during measurement of biosignals.

When the operation of the recirculation apparatus is stopped, a compressor pressurizing the evaporated gas, a gas tank storing a gas, an auxiliary device controlling a pressure, or the like, are required to prevent the pressure from increasing due to the evaporated gas inside the Dewar and the recirculation chamber. As a result, the system becomes significantly complex and requires a large space to house the device.

The present disclosure proposes a method for measuring a magnetic signal without stopping the recirculation apparatus by suppressing electromagnetic noise. Therefore, a compressor may be eliminated.

When low-temperature refrigerant reliquefaction is continuously used to measure a magnetic signal, a SQUID sensor did not operate or a system noise level was significantly increased due to an effect of magnetic noise generated from a cold head and external environmental noise. This is determined to be due to the fact that the inside and outside of a magnetically shielded room are not electromagnetically isolated from each other. A low-temperature refrigerant reliquefying circulation apparatus, which is currently in use, is generally formed of metal (for example, stainless steel) and used. In this case, external electromagnetic noise is transmitted through a metallic liquid helium transport pipe connected through a wall of the magnetically shielded room. In addition, when a metallic material (for example, a metallic liquid helium transport pipe) induced with electromagnetic noise passes through a magnetically shielded room formed of Ni permalloy (or u-metal) having high permeability, a magnetic field distribution inside the magnetically shielded room is significantly changed. Thus, a magnetic field measurement system disposed inside the magnetically shielded room becomes more sensitive to external induced noise. This is a cause of the operational stability of the magnetic field measurement system and a low signal-to-noise ratio during the measurement of minute magnetic signals.

Another disadvantage is that a low-temperature refrigerant reliquefying circulation apparatus according to the related art is separated from a return gas line, through which evaporated gas is transported to a reliquefying chamber, and a liquid helium transport pipe through which a liquefied liquid low-temperature refrigerant is transported to a low-temperature refrigerant storage container disposed inside the magnetically shielded room. A cold return gas line is exposed to the outside, which causes a large amount of water and ice to be formed on the liquid helium storage container (or a Dewar). Such a disadvantage mainly impedes attitude control of the device, such as rotation and tilt change.

An object is that low-temperature refrigerants used to cool a superconducting quantum interference device used in a minute magnetic signal measurement system are continuously circulated to develop a refrigerant lossless recirculation-based measurement apparatus. A method for effectively controlling an electromagnetic noise effect on a superconducting quantum interference device used as a sensor is required to develop such a continuous refrigerant lossless recirculation apparatus.

According to an embodiment of the present disclosure, there is provided a method for maintaining a vacuum at cryogenic temperature using a difference in thermal expansion coefficients when metallic and non-metallic objects are coupled to each other. Such a coupling structure may be used to implement a low-temperature refrigerant transport pipe connecting the inside and outside of a magnetically shielded room. With a method of manufacturing such a refrigerant transport pipe, a transport pipe penetrating through a magnetically shielded room electrically may enter an electrically insulating state to block electromagnetic noise introduced into the magnetically shielded room.

There is provided a method for integrating a low-temperature refrigerant transport pipe and a return gas line connected between a low-temperature refrigerant recirculation apparatus installed outside a magnetically shielded room and a low-temperature refrigerant storage container installed inside the magnetically shielded room. The integration of the return gas line and the low-temperature refrigerant transport pipe not only improves a refrigerant reliquefying rate but also simplifies a connection of the refrigerant recirculation apparatus between a reliquefier and the refrigerant storage container, which may significantly reduce the time required for system installation.

The present disclosure provides a method for connecting a rigid non-metallic pipe (for example, GFRP, CFRP, or the like) and a metal bellows at a liquid helium transport pipe. Accordingly, attitudes of the measuring apparatus and a subject may be effectively controlled.

Helium gas evaporated from a Dewar is converted into liquid helium using a helium gas reliquefying apparatus installed outside the magnetically shielded room, and then supplied to a Dewar inside the shielded room through a liquid helium transport pipe. This is done simultaneously with a system operation for measuring magnetoencephalography and magnetocardiography signals, and a liquid helium level in the Dewar is always maintained to be constant, so that liquid helium does not need to be replenished.

According to an embodiment of the present disclosure, the entirety or a portion of a liquid helium transport pipe, installed through a magnetically shielded room to transport a reliquefied refrigerant to a storage container (Dewar), is manufactured from a non-metallic material to block electromagnetic noise induced by a reliquefier or external environmental noise.

According to an embodiment of the present disclosure, by coupling two objects having significantly different thermal expansion coefficients using characteristics thereof, a vacuum may be maintained in a reliquefying chamber at cryogenic temperatures, and thus a refrigerant circulation apparatus may operate stably.

In addition, a refrigerant transport pipe and a gas circulation pipe connected between a refrigerant reliquefier and a refrigerant storage container may be integrated to increase refrigerant efficiency. In addition, the refrigerant reliquefier and the refrigerant storage container isolated by a magnetically shielded room may be coupled significantly simply, and thus attitude control of an apparatus for magnetic measurement may be easily performed.

Hereinafter, example embodiments will now be described more fully with reference to the accompanying drawings, in which some example embodiments are shown. Example embodiments may, however, be embodied in many different forms and should not be construed as being limited to the embodiments set forth herein. Rather, these example embodiments are provided so that this disclosure will be thorough and complete, and will fully convey the scope of example embodiments of the present disclosure to those of ordinary skill in the art. In the drawings, the thicknesses of layers and regions are exaggerated for clarity. Like reference characters and/or numerals in the drawings denote like elements.

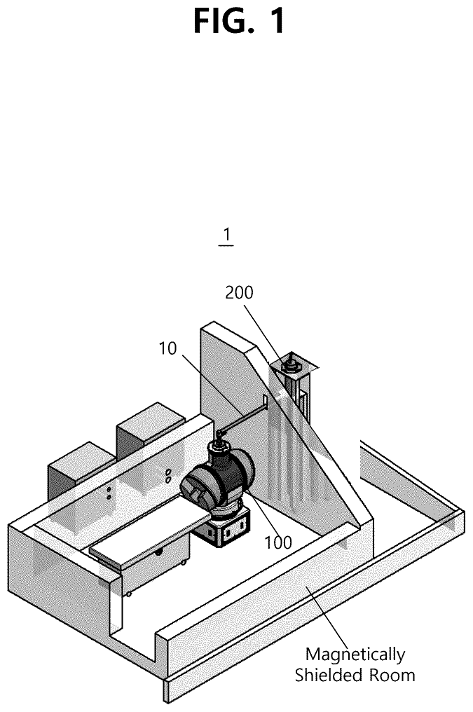

FIG. 1 is a perspective view illustrating a magnetic field measurement system according to an embodiment of the present disclosure.

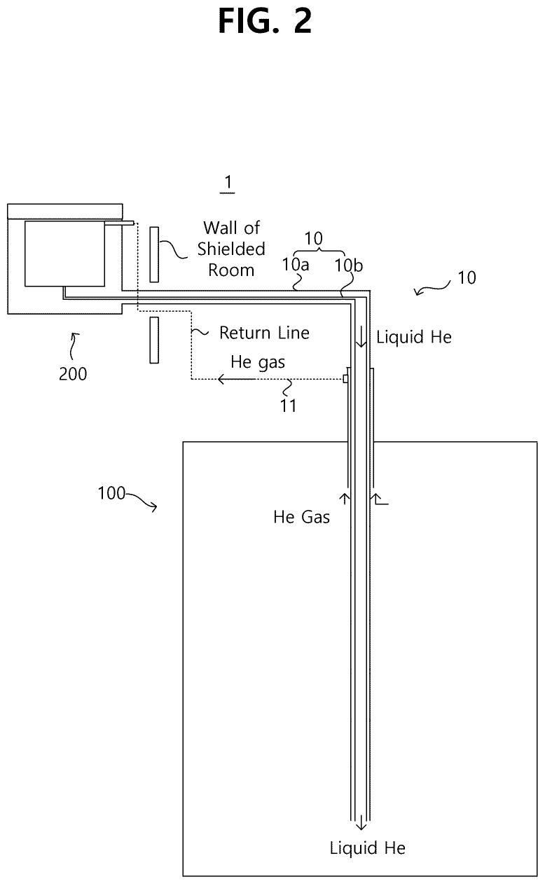

FIG. 2 is a conceptual diagram illustrating a magnetic field measurement system according to an embodiment of the present disclosure.

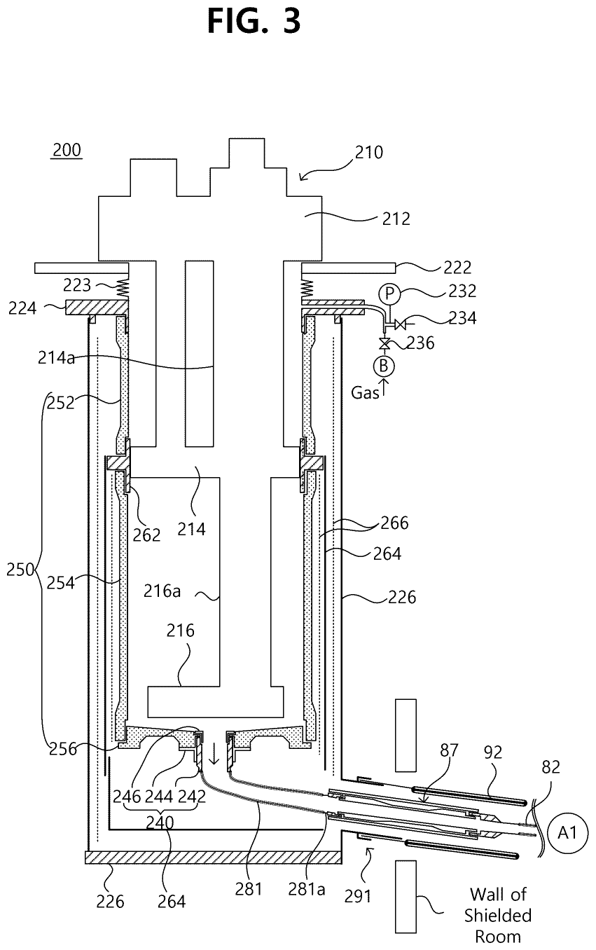

FIG. 3 is a conceptual diagram illustrating a liquid helium reliquefying circulation apparatus and a refrigerant transport pipe of FIG. 2.

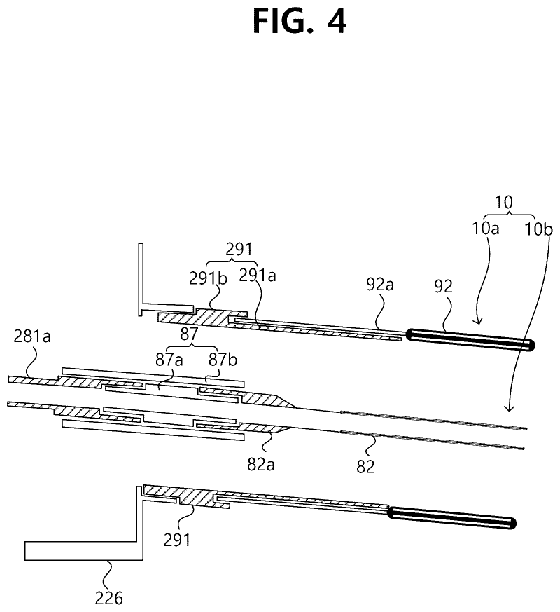

FIG. 4 is an enlarged view illustrating a connection portion of the liquid helium reliquefying circulation apparatus and the refrigerant transport pipe of FIG. 3.

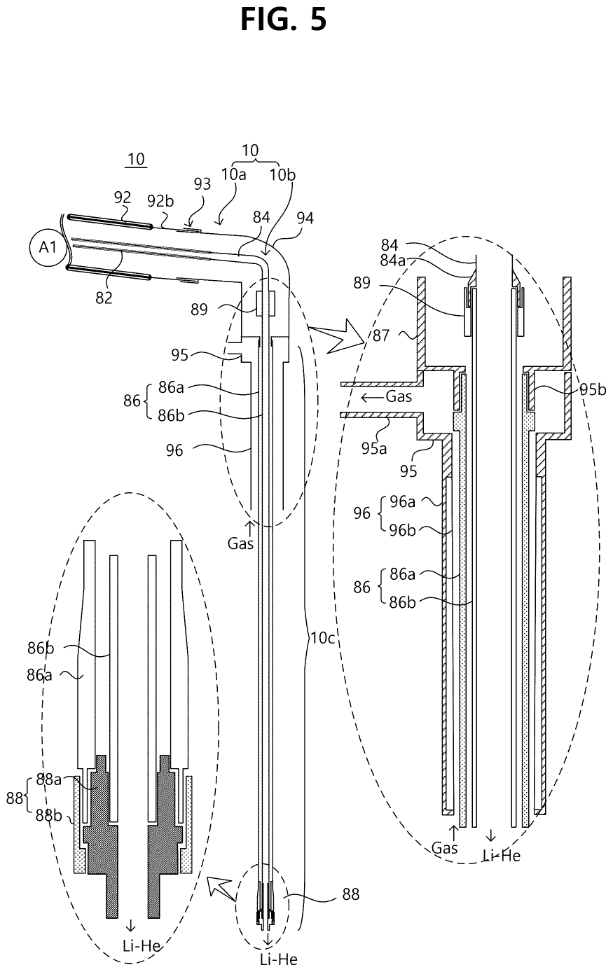

FIG. 5 is a conceptual diagram illustrating the refrigerant transport pipe of FIG. 3.

Referring to FIGS. 1 to 5, a magnetic field measurement system 1 according to an embodiment includes a liquid helium reliquefying circulation apparatus 200 and a magnetic field measurement apparatus 100. The magnetic field measurement apparatus 100 may include a liquid helium storage device or a Dewar. The magnetic field measurement apparatus 100 may be a magnetoencephalography or magnetocardiography measurement apparatus including a SQUID sensor.

The liquid helium reliquefying circulation apparatus 200 may include a pulse tube cryocooler 210, a thermal anchor 262, an upper inner chamber 252, a lower inner chamber 254, a heat shield 264, and a cryocooler inner pipe 281. The liquid helium reliquefying circulation apparatus 200 is disposed outside a magnetically shielded room. The magnetic field measurement apparatus 100 is disposed inside the magnetically shielded room.

The liquid helium reliquefying circulation apparatus 200 may eliminate a remote motor including a compressor, a helium gas storage tank, and a rotary valve.

Conventionally, the magnetic field measurement apparatus 100 may not operate the liquid helium reliquefying circulation apparatus 200 during a signal measurement operation to reduce noise. Accordingly, while the magnetic field measurement apparatus 100 is performing the signal measurement operation, generated helium gas may be stored in the helium gas storage tank. Then, by operating the compressor and the cryocooler 210 after the signal measurement operation is completed, the helium gas may be liquefied and supplied to the Dewar of the magnetic field measurement apparatus 100. However, the cryocooler 210 needs to operate even when the magnetic field measurement apparatus 100 is performing a measurement operation. To this end, the inner chamber 250 may be formed of an insulator to suppress transmission of electromagnetic noise, generated from the cryocooler 210, to the magnetic field measurement apparatus. Alternatively, the transport pipe 10 may include an insulating portion.

The pulse tube cryocooler 210 may be CryoMech PT-410. The pulse tube cryocooler 210 may include a cold head 212, a first stage heat exchanger 214, a second stage heat exchanger 216, a first stage regenerator 214a, and a second stage regenerator 216a.

The thermal anchor 262 may be coupled to the first stage heat exchanger 214. The thermal anchor 262 may include a cylindrical pipe and a washer formed on an outer side of the cylindrical pipe. A material of the thermal anchor 262 may be copper. The thermal anchor 262 may be cooled to a cryogenic temperature.

The upper internal chamber 252 may be formed of a dielectric material, and may be screw-coupled to the thermal anchor 262, coupled to a first flange 224 spaced apart from the thermal anchor 262, and disposed to surround the first stage regenerator 241a disposed on the first stage heat exchanger 214. The upper inner chamber 252 may be formed of carbon fiber reinforced plastic (CFRP) or glass fiber reinforced plastic (GFRP). The interior of the upper inner chamber 252 may be in a vacuum state.

The lower inner chamber 254 may be formed of a dielectric material, and may be screw-coupled to the thermal anchor 216 and disposed to surround the second stage heat exchanger 216 and the second stage regenerator 216a disposed on the second stage heat exchanger. The lower inner chamber 254 may be formed of carbon fiber reinforced plastic (CFRP) or glass fiber reinforced plastic (GFRP). The exterior of the lower inner chamber 254 may be in a vacuum state. The lower inner chamber 254 may include a lower plate 256. The lower inner chamber 254 and the lower plate 256 may be formed of carbon fiber reinforced plastic CFRP or glass fiber reinforced plastic (GFRP).

The heat shield 264 may be coupled to the thermal anchor 262 and disposed to surround the lower inner chamber. The heat shield 264 may include a metal mesh woven from mutually insulated metal wires and an insulating film.

A superinsulator layer 266 may be disposed between the heat shield 264 and the outer chamber 226. The superinsulator layer 266 may be disposed between the heat shield 264 and the lower inner chamber 254. The superinsulator layer 266 may be a structure in which a plurality of polymer films coated with aluminum are stacked.

The cryocooler inner pipe 281 may be connected to the lower plate 256 of the lower inner chamber 254 and formed of metal transporting liquid helium, and may have flexibility and elasticity. The cryocooler inner pipe 281 may include a bellows.

The lower plate 256 of the lower inner chamber may include a through-hole, and a connecting member 240 may connect the cryocooler inner pipe 281 and the lower plate 256.

The connecting member 240 may include a conductive nipple 242 inserted into the through-hole and screw-coupled; a socket 244 including a flange coupled to a lower surface of the lower plate 256 of the lower inner chamber and screw-coupled to the conductive nipple 242; and an insulating nipple 246 including a flange screw-coupled to an inner side surface of the conductive nipple 242 and connected to an upper surface of the lower plate 256 of the lower inner chamber. One end of the cryocooler inner pipe 281 may be continuously connected to the conductive nipple 242.

The conductive nipple 242 may include a thread on an outer side surface thereof. The conductive nipple 242 may be screw-coupled to the through-hole of the lower plate 256. The socket 244 has a thread on an inner side surface thereof, and the thread of the socket 244 may be screw-coupled to the thread of the conductive nipple 242. The insulating nipple 246 may be screw-coupled to an inner side surface of the conductive nipple 242 on an upper surface of the lower plate. Accordingly, the cryocooler inner pipe 281 may be electrically insulated from the lower inner chambers 254 and 256. Electrical insulation may prevent noise from being transmitted to the magnetic field measurement apparatus through the cryocooler inner pipe 281. The cryocooler inner pipe 281 may be a metallic bellows.

The second flange 222 may be disposed on the first flange 224 and coupled to a lower surface of the cold head 212. The first flange 224 and the second flange 222 may be connected by a bellows 223. The second flange 222 and the first flange 224 may be formed of stainless steel. The bellows 223 may be formed of stainless steel. The bellows 223 may reduce vibration.

The outer chamber 226, formed of metal, may be coupled to the first flange 224 and disposed to surround the heat shield 264. The outer chamber 226 may be formed of stainless steel.

The cryocooler outer pipe 291 may be connected to a lower end portion of the outer chamber 226 and coupled to an outer transport pipe 10a. The cryocooler inner pipe 281 may be disposed inside the cryocooler outer pipe 291. The cryocooler outer pipe 291 may be formed of stainless steel.

The liquid helium recondensation circulation apparatus 200 may include a lower inner chamber 254, formed of a dielectric material, and an upper inner chamber 252 formed of a dielectric material. When the liquid helium reliquefying circulation apparatus 200 operates, the vibration and electromagnetic noise generated by the liquid helium recondensation circulation apparatus 200 may not be transmitted to the cryocooler inner pipe 281.

The liquid helium reliquefying circulation apparatus 200 may further include a transport pipe 10 for transporting a refrigerant of the liquid helium reliquefying circulation apparatus to a magnetic field measurement apparatus 100.

According to an embodiment of the present disclosure, the transport pipe 10 for transporting a refrigerant of a refrigerant reliquefying apparatus to the magnetic field measurement apparatus may include an outer transport pipe 10a and an inner transport pipe 10b disposed inside the outer transport pipe. A superinsulator layer may be a structure in which a plurality of polymer films coated with aluminum are stacked. The superinsulator layer may be disposed to surround the inner transport pipe 10b.

The inner transport pipe 10b may include an inner insertion portion 86 inserted into the magnetic field measurement apparatus 100; an inner elbow portion 84 continuously connected to the insertion portion; and an inner flexible portion 82 connecting the inner elbow portion and a metallic cryocooler inner pipe of the refrigerant reliquefying apparatus.

The outer transport pipe 10b may include an outer insertion portion 96 inserted into the magnetic field measurement apparatus; an outer elbow portion 94 continuously connected to the outer insertion portion; and an outer flexible portion 92 connecting the outer elbow portion and a metallic cryocooler inner pipe of the refrigerant reliquefying apparatus. The outer flexible portion 92 of the outer transport pipe 10a may include a flexible portion formed of an insulating material.

The outer transport pipe 10a may include an outer insertion portion 96; an outer elbow portion 94; and an outer flexible portion 92. The outer flexible portion 92 of the outer transport pipe may be a bellows formed of PTFE.

The cryocooler outer pipe 291 may be welded to the outer chamber 226. The cryocooler outer pipe 291 may include a guide tube 291a and a coupling tube 291b covering the guide tube 291a. The cryocooler outer pipe 291 may be formed of metal. Specifically, the cryocooler outer pipe 291 may be formed of stainless steel.

The outer flexible portion 92 may be formed of an insulating material and may include sleeves 92a and 92b at each end. The sleeve 92a may be screw-coupled to an outer surface of the guide tube 291a. Additionally, the sleeve 92a may be screw-coupled to an inner surface of the connection tube 291b.

The outer flexible portion 92 of the outer transport pipe 10a may be formed of polytetrafluoroethylene (PTFE), and opposite ends of the outer flexible portion 92 may include sleeves 92a and 92b, respectively. The outer flexible portion 92 of the outer transport pipe 10a may pass through a through-hole or slit in the magnetically shielded room.

The outer elbow portion 94 may be bent 110 degrees and may be formed of metal. The outer elbow portion 94 of the outer transport pipe 10a may include a connection portion 93 coupled to the outer flexible portion 92. The connection portion 93 may be connected to the outer flexible portion 92 using a structure (a guide tube and a coupling tube), similar to that of the cryocooler outer pipe 291.

The outer insertion portion 96 of the outer transport pipe may be connected to the outer elbow portion 94 of the outer transport pipe. The outer insertion portion 96 of the outer transport pipe may be a double-tube structure formed of metal. The outer insertion portion 96 may be a double-tube structure formed of metal and may include an inner tube 96b and an outer tube 96a.

The outer elbow portion 94 of the outer transport pipe 10a may further include a return gas connection portion 95. The return gas connection portion 95 may be connected to the outer elbow portion 94 of the outer transport pipe to provide a fitting pipe 95a through which return gas may flow.

The inner transport pipe 10b includes an inner insertion portion 82; an inner elbow portion 84; and an inner flexible portion 86.

The cryocooler inner pipe 281 may be connected to the inner chamber 250. The cryocooler inner pipe 281 may include a metal bellows 281 and a sleeve 281a connected to the bellows. Specifically, the cryocooler inner pipe 281 may be formed of stainless steel.

The inner flexible portion 82 may include a sleeve 82a at one end thereof. The sleeve 82a may be continuously connected to the inner flexible portion 82. The inner flexible portion 82 may be a bellows formed of metal. Specifically, the inner flexible portion 82 may be a bellows formed of stainless steel.

The inner flexible portion 82 may include a metal inner bellows; and an insulating inner union 87 connecting the metal inner bellows to the metal cryocooler inner pipe 281 of the refrigerant reliquefying apparatus.

The outer flexible portion 92 of the outer transport pipe 10a and the insulating inner union 87 may pass through a through-hole or slit in the magnetically shielded room. Accordingly, the transmission of electromagnetic noise, transmitted through the transport pipe 10 into the magnetic field measurement apparatus, may be suppressed.

The insulating inner union 87 may include a first nipple 87a screw-coupled to the sleeve 281a of the cryocooler inner pipe 281 and screw-coupled to the sleeve 82a of the inner bellows; and a second nipple 87b screw-coupled to the first nipple 87a and screw-coupled to the sleeve 281a of the cryocooler inner pipe and the sleeve 82a of the inner bellows. An outer side surface of one end of the first nipple 87a may be screw-coupled to an inner side surface of the sleeve 281a. An outer side surface of the other end of the first nipple 87a may be screw-coupled to an inner side surface of the sleeve 82a. One end of the second nipple 87b may be screw-coupled to an outer side surface of the sleeve 82a, and the other end of the second nipple 87b may be screw-coupled to an outer side surface of the sleeve 281a. The insulating inner union 87 may be formed of glass fiber reinforced plastic (GFRP).

The inner elbow portion 84 may be bent 110 degrees and may be a pipe formed of metal. The inner elbow portion 84 may be a rigid pipe shape that is continuously connected to the inner flexible portion 82. The inner elbow portion 84 may be connected to the inner flexible portion 82 by welding.

The inner insertion portion 86 may be formed of an insulating material and may be a double-tube structure including an inner tube 86b and an outer tube 86a. A material of the inner insertion portion 86 may be formed of glass fiber reinforced plastic (GFRP). The inner tube 86b of the inner insertion portion 86 may be coupled to the inner elbow portion 84 by an insulating joint 89.

The inner elbow portion 84 may include a sleeve 84a. The sleeve 84a may be screw-coupled to the outer side surface of the inner tube 86b. The insulating joint 89 may be connected to the outer side surface of the inner tube 86b and screw-coupled to the outer side surface of the sleeve 84a.

The outer tube 86a of the double tube of the inner insertion portion 86 may be coupled to the double tube of the outer insertion portion 96 to seal the inner insertion portion.

The outer elbow portion 94 of the outer transport pipe 10a may further include a return gas connection portion 95. The return gas connection portion 95 may be connected to the outer elbow portion 94 of the outer transport pipe 10a to provide a fitting pipe 95a through which return gas may flow. The return gas connection portion 95 may have a coaxial structure, and the inner pipe 95b of the return gas connection portion 95 may be screw-coupled to the outer tube 86a of the double tube of the inner insertion portion.

The outer insertion portion 96 may be shorter than the inner insertion portion 86. Helium gas may move through the return path via an end of the outer insertion portion 96.

The inner insertion portion 86 may provide liquid helium to the magnetic field measurement apparatus 100. An end of the inner insertion portion 86 may include a sealing means 88 to seal the double-tube structure. The sealing means 88 may use two tube sleeves 88a and 88b to seal a portion between the inner tube 86b and outer tube 86a of the inner insertion portion 86. The tube sleeves 88a and 88b may be screw-coupled to each other.

The return gas line 11 may connect the return gas connection portion 95a to the gas inlet formed in the first flange 224. The return gas line 11 may be connected to the first valve 236 and the second valve 234. The first valve 236 may control a flow of the return gas, and the second valve 234 may open and close the connection to an additional helium storage device. A pressure sensor 232 may be connected to the return gas line to measure a pressure.

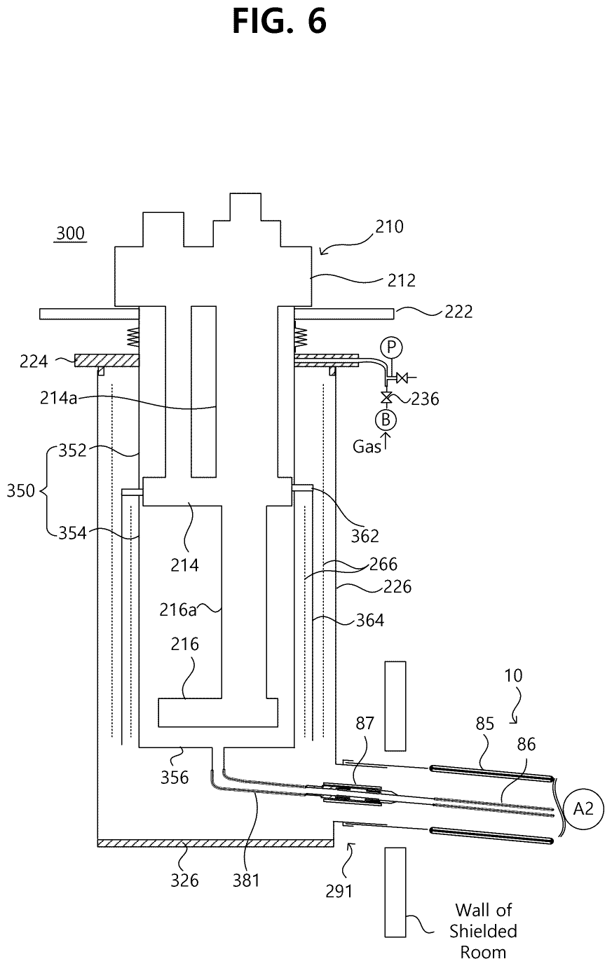

FIG. 6 is a conceptual diagram illustrating a liquid helium reliquefying circulation apparatus according to another embodiment of the present disclosure.

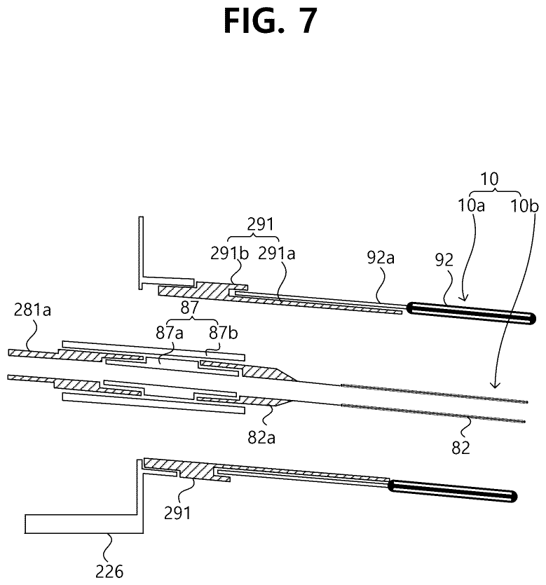

FIG. 7 is an enlarged view illustrating a connection part of the liquid helium reliquefying circulation apparatus and the refrigerant transport pipe of FIG. 6.

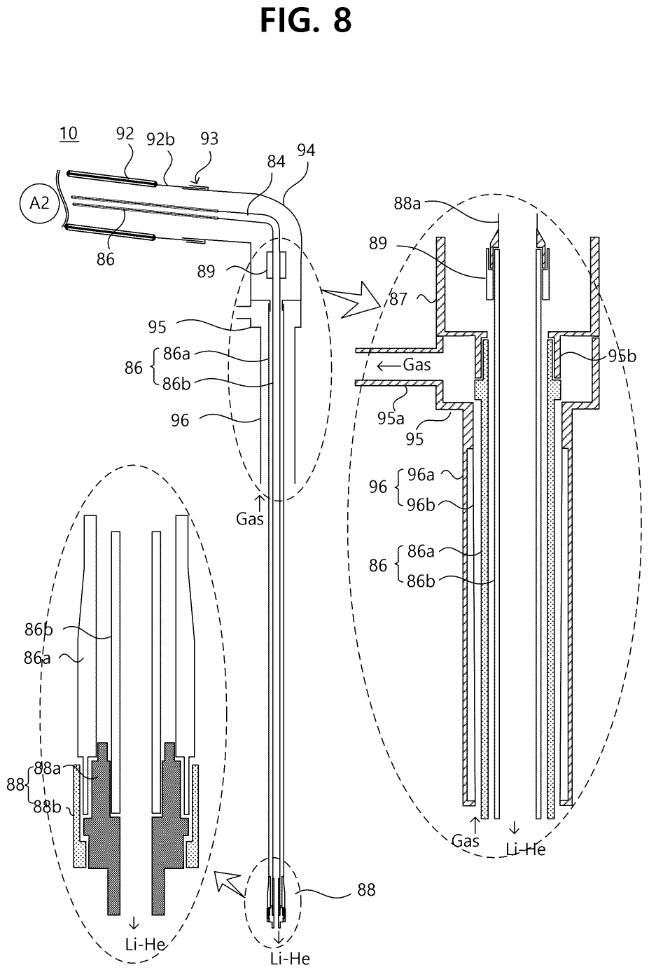

FIG. 8 is a conceptual diagram illustrating the refrigerant transport pipe of FIG. 6.

Referring to FIGS. 6 to 8, a liquid helium recondensation circulation apparatus 300 includes:
a pulse tube cryocooler 210 including a cold head 212, a first stage heat exchanger 214, and a second stage heat exchanger 216; a thermal anchor 362 coupled to the first stage heat exchanger 214; an upper inner chamber 352 formed of metal, coupled to the thermal anchor 362, coupled to a first flange 224 spaced apart from the thermal anchor, and disposed to surround a first stage regenerator 214a disposed on the first stage heat exchanger 214; a lower inner chamber 354 formed of metal, coupled to the thermal anchor 362 and disposed to surround the second stage heat exchanger 216 and a second stage regenerator 216a disposed on the second stage heat exchanger; a heat shield 364 coupled to the thermal anchor 362 to surround the lower inner chamber; and a cryocooler inner pipe 381 formed of metal, connected to a lower plate 356 of the lower inner chamber 354, transporting liquid helium, and having flexibility.

The thermal anchor 362 may be coupled to the first stage heat exchanger 214. The thermal anchor 362 may include a cylindrical pipe and a washer formed on an outer side of the cylindrical pipe. A material of the thermal anchor 362 may be copper. The thermal anchor 362 may be cooled to a cryogenic temperature.

The upper inner chamber 352 may be formed of metal and screw-coupled to the thermal anchor 362, coupled to the first flange 224 spaced apart from the thermal anchor 362, and disposed to surround the first stage regenerator 214a disposed on the first stage heat exchanger 214. The upper inner chamber 352 may be formed of stainless steel. The interior of the upper inner chamber 352 may be in a vacuum state.

The lower inner chamber 354 may be formed of metal, screw-coupled to the thermal anchor 362, and disposed to surround the second stage heat exchanger 216 and the second stage regenerator 216a disposed on the second stage heat exchanger. The lower inner chamber 354 may be formed of stainless steel. The exterior of the lower inner chamber 354 may be in a vacuum state. The lower inner chamber 354 may include a lower plate 356. A material of the lower inner chamber 354 and the lower plate 356 may be metal.

The heat shield 364 may be coupled to the thermal anchor 362 and disposed to surround the lower inner chamber. The heat shield 364 may include a metal mesh, woven from insulated wires, and an insulating film.

A superinsulator layer 266 may be disposed between the heat shield 364 and the outer chamber 226. The superinsulator layer 266 may be disposed between the heat shield 364 and the lower inner chamber 354. The superinsulator layer 266 may be a structure in which a plurality of polymer films coated with aluminum are stacked.

A cryocooler inner pipe 381 may be connected to a lower plate 356 of the lower inner chamber 354 and formed of metal transporting liquid helium, and may have flexibility and elasticity. The cryocooler inner pipe 381 may include a bellows.

The lower plate 356 of the lower inner chamber may connect the cryocooler inner pipe 381.

A second flange 222 may be disposed on the first flange 224 and coupled to a lower surface of the cold head 212. The first flange 224 and the second flange 222 may be coupled by a bellows 223. The second flange 222 and the first flange 224 may be formed of stainless steel. The bellows 223 may be formed of stainless steel. The bellows 223 may reduce vibration.

The outer chamber 226, formed of metal, may be coupled to the first flange 224 and disposed to surround the heat shield 264. The outer chamber 226 may be formed of stainless steel.

The cryocooler outer pipe 291 may be connected to a lower end portion of the outer chamber 226 and coupled to an outer transport pipe 10a. The cryocooler inner pipe 381 may be disposed inside the cryocooler outer pipe 291. The cryocooler outer pipe 291 may be formed of stainless steel.

The liquid helium reliquefying circulation apparatus 300 may be cooled by the thermal anchor 362 and the heat shield 364, and insulated by the superinsulator layer 266.

The liquid helium reliquefying circulation apparatus 300 may further include a transport pipe 10 for transporting a refrigerant to the magnetic field measurement apparatus 100.

The transport pipe 10 may include an outer transport pipe 10a and an inner transport pipe 10b disposed inside the outer transport pipe.

The inner transport pipe 10a may include an inner insertion portion 86 inserted into the magnetic field measurement apparatus 100; an inner elbow portion 84 continuously connected to the insertion portion; and an inner flexible portion 86 connecting the elbow portion and the cryocooler inner pipe, formed of metal, of the refrigerant reliquefying apparatus.

The outer transport pipe 10b may include an outer insertion portion 96 inserted into the magnetic field measurement apparatus 100; an outer elbow portion 94 continuously connected to the outer insertion portion; and an outer flexible portion 82 connecting the outer elbow portion and the cryocooler inner pipe, formed of metal, of the refrigerant reliquefying apparatus. The outer flexible portion 92 of the outer transport pipe may include a flexible portion of an insulating material. The outer flexible portion 92 of the outer transport pipe and the insulating inner union 87 may pass through a through-hole or slit of a magnetically shielded room. Accordingly, transmission of electromagnetic noise, transmitted through the transport pipe 10, into the magnetic field measurement apparatus may be suppressed.

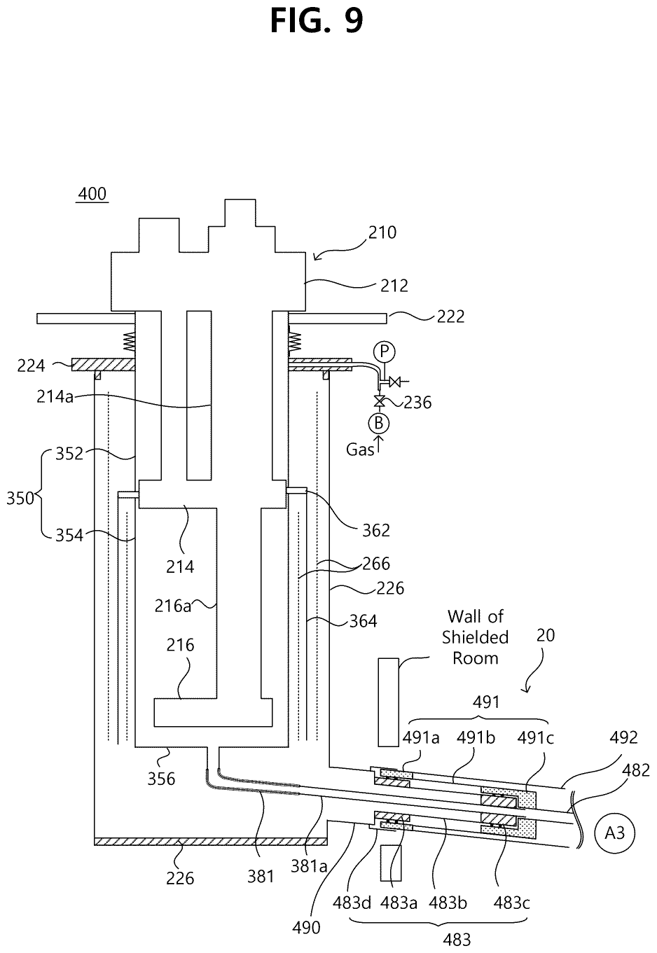

FIG. 9 is a conceptual diagram illustrating a liquid helium reliquefying circulation apparatus according to another embodiment of the present disclosure.

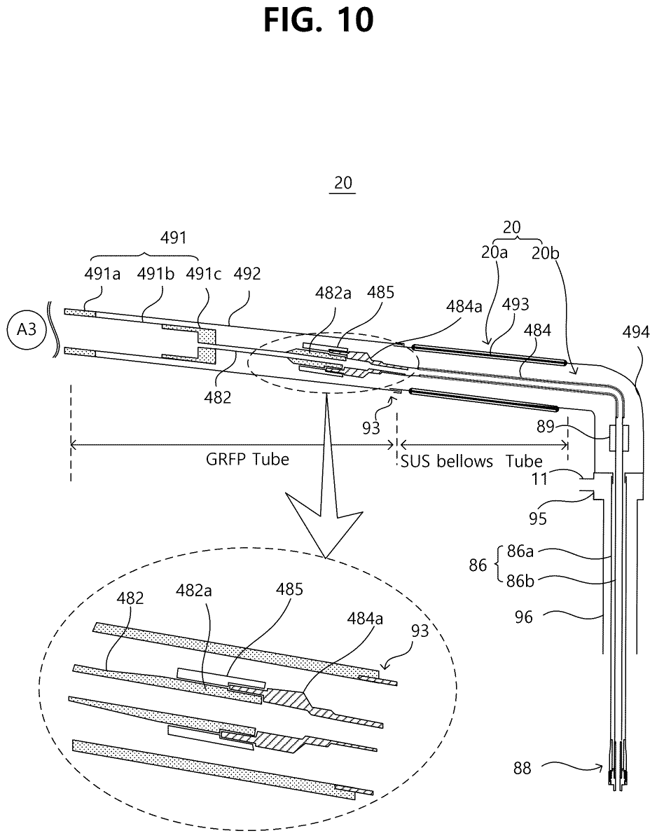

FIG. 10 is an enlarged view illustrating a refrigerant transport pipe and connection portion of FIG. 9.

Referring to FIGS. 9 and 10, a liquid helium reliquefying circulation apparatus 400 includes: a pulse tube cryocooler 210 including a cold head 212, a first stage heat exchanger 214, and a second stage heat exchanger 216; a thermal anchor 362 coupled to the first stage heat exchanger 214; an upper inner chamber 352 formed of metal, coupled to the thermal anchor 362, coupled to a first flange 224 spaced apart from the thermal anchor, and disposed to surround a first stage regenerator 214a disposed on the first stage heat exchanger 214; a lower inner chamber 354 formed of metal, coupled to the thermal anchor 362, and disposed to surround a second stage regenerator 216a disposed on the second stage heat exchanger; a heat shield 364 coupled to the thermal anchor 362 and disposed to surround the lower inner chamber; and a cryocooler inner pipe 381 connected to a lower plate 356 of the lower inner chamber 354, formed of metal transporting liquid helium, and having flexibility.

The liquid helium reliquefying circulation apparatus 400 may further include a transport pipe 20 for transporting a refrigerant of the liquid helium reliquefying circulation apparatus 400 to the magnetic field measurement apparatus.

The transport pipe 20 includes: an outer transport pipe 492; an inner transport pipe 482 disposed inside the outer transport pipe; and an outer connection portion 491 connecting one end of the outer transport pipe and one end of the inner transport pipe. The outer connection portion 491 may be formed of an insulating material. Specifically, the outer connection portion 491 may be formed of GFRP.

The liquid helium reliquefying circulation apparatus 400 may include: cryocooler inner pipes 381a and 381, each having one end connected to an inner chamber 350; a cryocooler outer pipe 490 having one end connected to the outer chamber 226; and an inner connection portion 483 connecting the other end of the cryocooler outer pipe 490 and the other end of the cryocooler inner pipe 381a. The outer connection portion 491 and the inner connection portion 483 are sealed to each other. The outer connection portion 491 and the inner connection portion 483 may be decomposed and coupled to each other.

The outer connection portion 491 may include: a first outer connection portion 491a connecting the outer transport pipe 492 and an outer intermediate pipe 491b to each other; and a second outer connection portion 491c connecting the intermediate pipe 491b and the inner transport pipe 482 to each other. The outer connection portion 491 may be formed of an insulating material. The first outer connection portion 491a may be screw-coupled to the outer transport pipe. The first outer connection portion 491a may be screw-coupled to the intermediate pipe. The second outer connection portion 491c may be screw-coupled to the intermediate pipe. The second outer connection portion 491c may be screw-coupled to the inner pipe.

The inner connection portion 483 may include: a first inner connection portion 483a connecting the cryocooler outer pipe 490 and the inner intermediate pipe 483b to each other; and a second inner connection portion 483c connecting the inner intermediate pipe 483b and the cryocooler inner pipe 481a to each other. The inner connection portion 483 may be formed of metal. The first inner connection portion 483a may be welded to the cryocooler outer pipe 490 and the inner intermediate pipe 483b. The second inner connection portion 483c may be welded to the inner intermediate pipe 483b and the cryocooler inner pipe 481a.

The first outer connection portion 491a may be coupled to the first inner connection portion 483a to be sealed, and the second outer connection portion 491c may be coupled to the second inner connection portion 493c to be sealed. A sealing means may be an O-ring. The first outer connection portion 491a may be decomposed and coupled to the first inner connection portion 483a.

The outer transport pipe 492 may further include an outer bellows portion 493 formed of metal and an outer elbow portion 494. The outer elbow portion 494 may be bent 110 degrees and may be a pipe formed of metal. The outer transport pipe 492 may be screw-coupled to the outer corrugated pipe portion 493 using a connection means 93 (a guide tube and a connection tube). The outer bellows pipe portion 493 and the outer elbow portion 494 may be welded.

The inner transport pipe 482 may further include an inner bellows pipe 484 formed of metal. The inner transport pipe 482 may be screw-connected to the inner bellows pipe 484. The inner corrugated pipe 484 may pass through the outer elbow portion 494. The inner transport pipe 482 may be screw-coupled to a sleeve 484a of the inner bellows pipe 484. An insulating auxiliary pipe 485, formed of insulating material, may be screw-coupled to the sleeve 484a and the inner transport pipe 482.

The outer transport pipe 492 may further include an outer insertion portion 96 inserted into the magnetic field measurement apparatus. The inner transport pipe 482 may further include an inner insertion portion 86 inserted into the magnetic field measurement apparatus.

The outer insertion portion 96 may be formed of metal, and may have a double-tube structure including an inner tube 96b and an outer tube 96a.

The inner insertion portion 86 may be formed of an insulating material, and may have a double-tube structure including an inner tube 86b and an outer tube 86a.

The outer tube 86a of the double-tube structure of the inner insertion portion 86 may be coupled to the double-tube structure of the outer insertion portion 96 to seal the inner insertion portion.

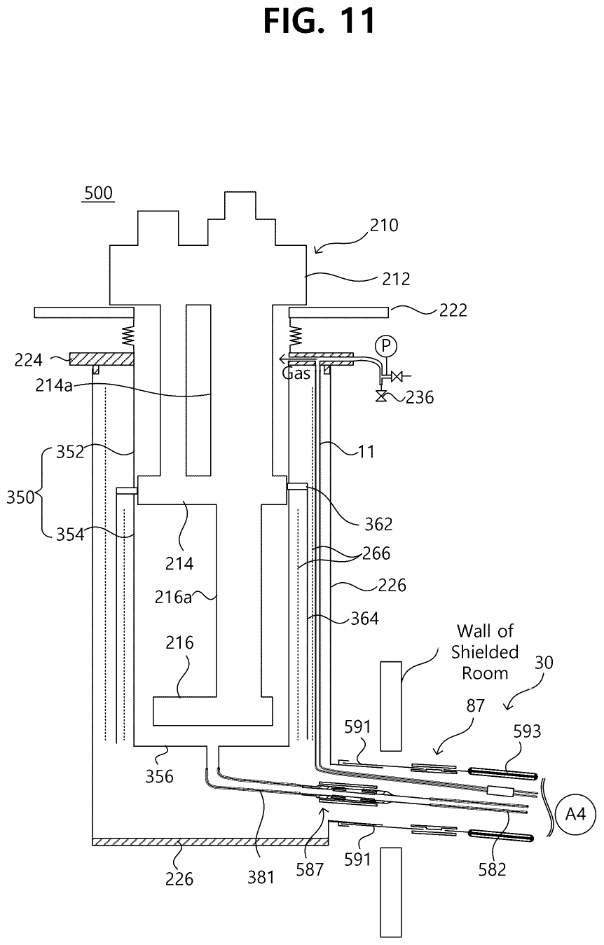

FIG. 11 is a conceptual diagram illustrating a liquid helium reliquefying circulation apparatus according to another embodiment of the present disclosure.

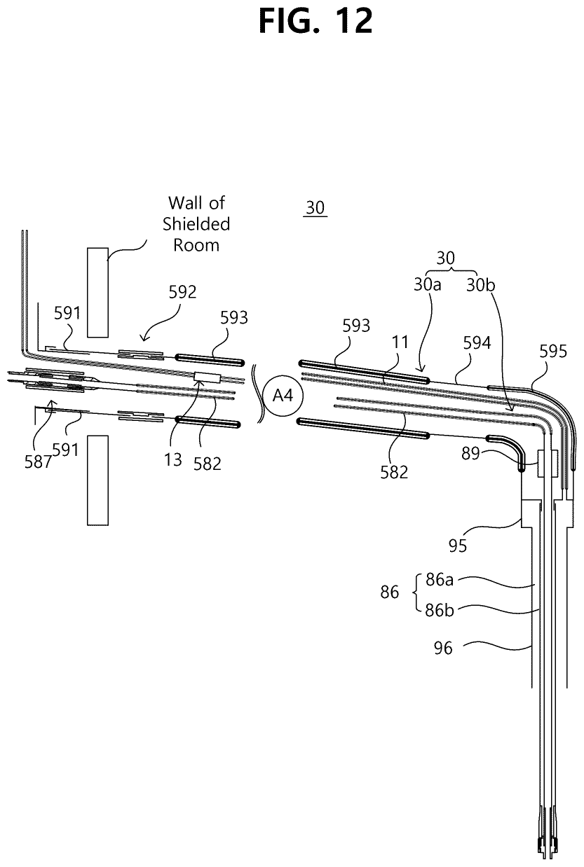

FIG. 12 is a drawing illustrating a refrigerant transport pipe of FIG. 11.

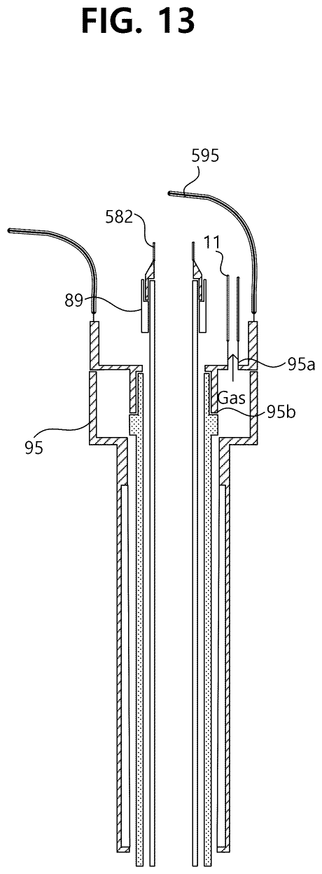

FIG. 13 is an enlarged view illustrating an elbow portion of the refrigerant transport pipe of FIG. 12.

Referring to FIGS. 11 to 13, a liquid helium reliquefying circulation apparatus 500 may include: a pulse tube cryocooler 210 including a cold head 212, a first stage heat exchanger 214, and a second stage heat exchanger 216; a thermal anchor 362 connected to the first stage heat exchanger 214; an upper inner chamber 352 formed of metal, coupled to the thermal anchor 262, coupled to a first flange 224 spaced apart from the thermal anchor, and disposed to surround a first stage regenerator 214a disposed on the first stage heat exchanger 214; a lower inner chamber 354 formed of metal, coupled to the thermal anchor 262 and disposed to surround the second stage heat exchanger 216 and a second stage regenerator 216a disposed on the second stage heat exchanger; a heat shield 364 connected to the thermal anchor 362 and disposed to surround the lower inner chamber; and a cryocooler inner pipe 381 connected to a lower plate 356 of the lower inner chamber 354, formed of metal transporting liquid helium, and having flexibility.

The liquid helium reliquefying circulation apparatus 500 may further include a transport pipe 30 for transporting a refrigerant of the liquid helium reliquefying circulation apparatus to a magnetic field measurement apparatus.

The transport pipe 30 may include: an outer transport pipe 30a; and an inner transport pipe 30b disposed inside the outer transport pipe.

The transport pipe 30 may include a return gas line 11 disposed inside the outer transport pipe 30a and branching off from the outer insertion portion.

The inner transport pipe 30b may include: an inner insertion portion 86 inserted into the magnetic field measurement apparatus; and an inner flexible portion 582 connecting the inner insertion portion 86 and a cryocooler inner pipe, formed of metal, of the refrigerant reliquefying apparatus.

The outer transport pipe 30a may include: an outer insertion portion 96 inserted into the magnetic field measurement apparatus; an outer elbow portion 595 continuously connected to the outer insertion portion; and an outer flexible portion 593 connecting the outer elbow portion and the cryocooler outer pipe, formed of metal, of the refrigerant reliquefying apparatus.

The transport pipe 30 may further include a return gas line 11 disposed inside the outer transport pipe and branching off from the outer insertion portion.

The outer connection portion 592 may be connected to the outer flexible portion 593, and may be formed of an insulating material.

The outer flexible portion 593 may be a bellows pipe formed of metal. The outer flexible portion 593 may connect the outer connection portion 592 to the cryocooler outer pipe 591. The outer connection portion 592 may connect the outer flexible portion 593 and the cryocooler outer pipe 591 by screw-coupling an inner pipe and an outer pipe formed of insulating material.

The inner connection portion 587 may be connected to the inner flexible portion 582, and may be formed of an insulating material. The inner flexible portion 582 may be a metal bellows pipe formed of metal.

The inner flexible portion 582 may be coupled to the cryocooler inner pipe 381 through an inner coupling portion 587. The inner coupling portion 587 may connect the inner flexible portion 582 and the cryocooler inner pipe 381 by screw-coupling an inner pipe and an outer pipe formed of an insulating material.

The outer transport pipe 30a may further include a straight portion 594 connecting the outer flexible portion 593 and the outer elbow portion 595. The outer elbow portion 595 may be a bellows pipe formed of metal. The straight portion 594 may be a pipe formed of metal.

The return gas line 11 may be a bellows pipe formed of metal. The return gas line 11 may further include an insulating joint 13 for electrical insulation.

The outer elbow portion 595 of the outer transport pipe 30a may further include a return gas connection portion 95. The return gas connection portion 95 may be connected to the outer elbow portion 595 to provide a fitting pipe 95a through which return gas may flow. The fitting pipe 95a may be disposed along the outer elbow portion 595 within the return gas connection portion 95.

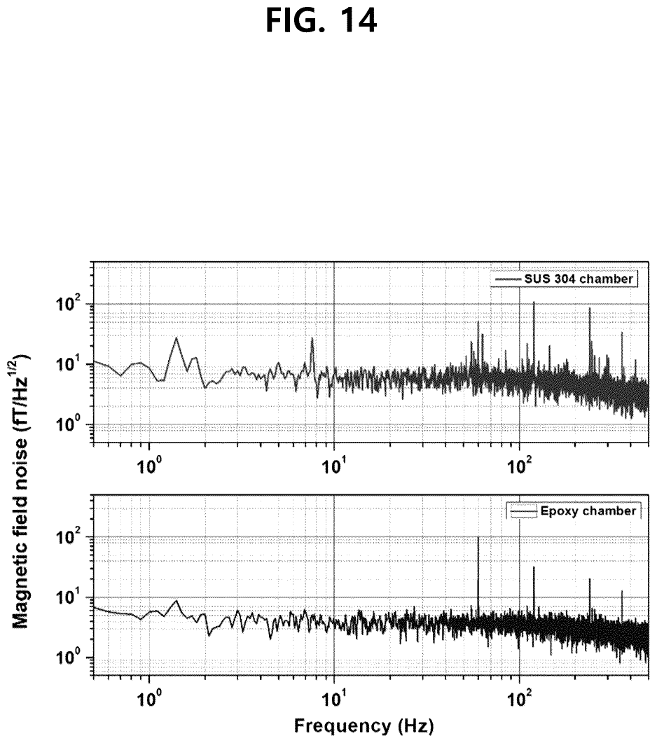

FIG. 14 is a frequency spectrum diagram illustrating noise of a liquid helium reliquefying circulation apparatus according to an embodiment of the present disclosure and noise of a conventional liquid helium reliquefying apparatus.

Referring to FIGS. 3 and 14, the reliquefier inner chamber 250 of FIG. 3 may employ an inner upper chamber and an inner lower chamber formed of GFRP. In addition, the outer flexible portion 92 of the outer transport pipe 10a and the insulating inner union 87 may pass through a through-hole or slit of the magnetically shielded room.

In the conventional liquid helium reliquefying apparatus, when an inner upper chamber and an inner lower chamber are formed of metal and a refrigerant transport pipe is a conductor, cryocooler magnetic noise is observed at around 1.4 Hz and 10 Hz. In addition, environmental noise is observed around 60 Hz.

On the other hand, in the liquid helium reliquefying apparatus 200 according to the present disclosure, when a reliquefier inner chamber employs an inner upper chamber and an inner lower chamber formed of GFRP and an insulating refrigerant transport pipe is used, cryocooler magnetic noise may be removed at around 1.4 Hz and 10 Hz. In addition, environmental noise may be removed around 60 Hz. Accordingly, a signal-to-noise ratio of the magnetic field measurement apparatus may be significantly increased.

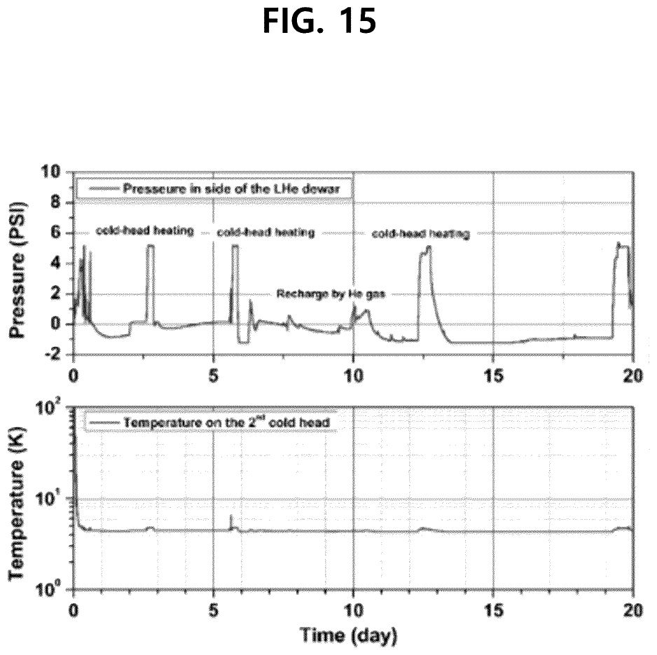

FIG. 15 is a diagram illustrating operating characteristics of a liquid helium reliquefying apparatus according to an embodiment of the present disclosure.

Referring to FIG. 15, in a liquid helium reliquefying apparatus 200 according to an embodiment of the present disclosure, an inner pressure of a Dewar and a temperature of a second stage heat exchanger 216 may be displayed. The temperature of the second stage heat exchanger 216 may be about 4K, which is constant. On the other hand, the inner pressure of the Dewar may increase due to heating of a cold head. When a pressure of a return line (or the pressure of the Dewar or the pressure of the inner chamber) decreases to 0.1 PSI or less, pressures of the Dewar and an inner chamber of a reliquefier may be maintained at a predetermined value or more by heating the cold head.

Refilling with helium gas may increase a level of liquid helium in the Dewar. In other words, after injecting helium gas into the liquid helium reliquefying apparatus from the outside and liquefying the injected helium gas, a refrigerant may be transported to the Dewar through a refrigerant transport pipe.

Accordingly, the liquid helium reliquefying apparatus and the magnetic field measurement apparatus may stably operate without stopping.

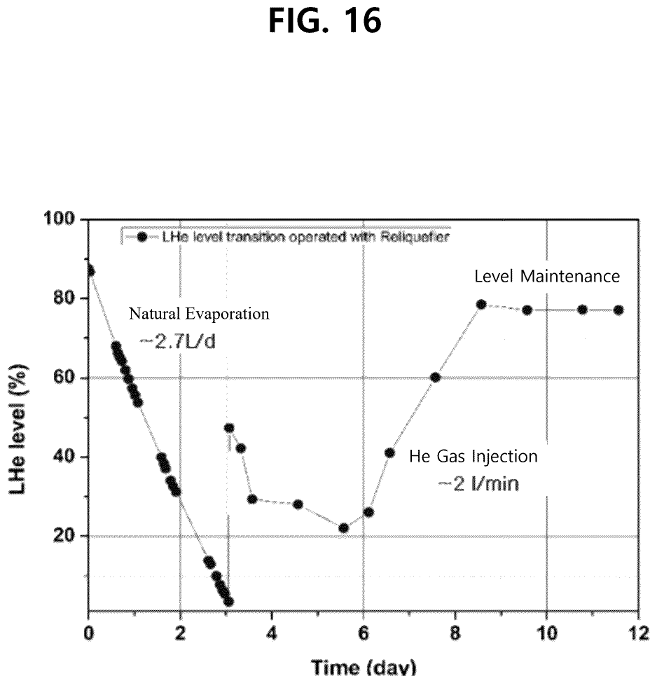

FIG. 16 is a diagram illustrating a helium level of a Dewar by a liquid helium reliquefying apparatus according to an embodiment of the present disclosure.

Referring to FIG. 16, a level of liquid helium (LHe) may be reduced by natural evaporation. On the other hand, a constant LHe level may be maintained by injecting He gas.

As a result, the He gas injection may allow the liquid helium reliquefying apparatus and the magnetic field measurement apparatus to stably operate without stopping.

Although the present disclosure and its advantages have been described in detail, it should be understood that various changes, substitutions and alterations can be made herein without departing from the spirit and scope of the disclosure as defined by the following claims.

### EXPLANATION OF REFERENCE SIGNS

200: Liquid Helium Reliquefying Circulation Apparatus; 210: Pulse Tube Cryocooler; 262: Thermal Anchor; 252: Upper Inner Chamber; 254: Lower Inner Chamber; 264: Heat Shield

1. A liquid helium reliquefying circulation apparatus comprising:
a pulse tube cryocooler comprising a cold head, a first stage heat exchanger, and a second stage heat exchanger;
an upper inner chamber disposed to surround a first stage regenerator disposed on the first stage heat exchanger;
a lower inner chamber disposed to surround the second stage heat exchanger and a second stage regenerator disposed on the second stage heat exchanger; and
a cryocooler inner pipe, connected to a lower plate of the lower inner chamber, formed of metal, transporting liquid helium, and having flexibility.

2. The liquid helium reliquefying circulation apparatus as set forth in claim 1,
The upper inner chamber and the lower inner chamber are formed of glass fiber reinforced plastic (GFRP).

3. The liquid helium reliquefying circulation apparatus as set forth in claim 1, further comprising a transport pipe assembly,
wherein the transport pipe assembly comprises an outer transport pipe and an inner transport pipe disposed inside the outer transport pipe,
wherein the transport pipe assembly includes an insulation portion to reduce a magnetic and electric noise.

4. The liquid helium reliquefying circulation apparatus as set forth in claim 3,
the inner transport pipe comprises a flexible section to reduce vibration noise.

5. The liquid helium reliquefying circulation apparatus as set forth in claim 1,
further at least one comprising:
a thermal anchor coupled to the first stage heat exchanger;
a heat shield disposed coupled to the thermal anchor and to disposed to surround the lower inner chamber;
a first flange spaced apart the thermal anchor;
a second flange disposed on the first flange and coupled to a lower surface of the cold head; and
a superinsulator layer disposed between the heat shield and an outer chamber;
wherein the first flange and the second flange are connected by a bellows.

6. The liquid helium reliquefying circulation apparatus as set forth in claim 1, further comprising a transport pipe assembly and a return gas line,
wherein the transport pipe assembly and the return gas line are integrated.

7. The liquid helium reliquefying circulation apparatus as set forth in claim 1,
wherein the upper inner chamber and the lower inner chamber are made of metal.

8. The liquid helium reliquefying circulation apparatus as set forth in claim 1, further comprising a transport pipe assembly;
wherein the transport pipe assembly comprises:
an outer transport pipe; and
an inner transport pipe situated inside the outer transport pipe;
wherein the inner transport pipe comprises:
an inner insertion portion that is inserted into a magnetic field measuring apparatus;
an inner elbow portion connected to the inner insertion portion; and
an inner flexible portion that connects the inner elbow portion to the cryocooler inner pipe.

9. The liquid helium reliquefying circulation apparatus as set forth in claim 8, wherein the outer transport pipe comprises:
an outer insertion portion that is inserted into the magnetic field measurement apparatus;
an outer elbow portion connected to the outer insertion portion; and
an outer flexible portion that connects the outer elbow portion to a cryocooler outer pipe;
wherein the outer flexible portion of the outer transport pipe is made of PTFE bellows, providing the necessary flexibility.

10. The liquid helium reliquefying circulation apparatus as set forth in claim 8,
wherein the inner flexible portion of the inner transport pipe comprise a metal inner bellows,
wherein the inner flexible portion of the inner transport pipe comprises an insulating inner union,
wherein the insulating inner union connects the cryocooler inner pipe and the metal inner bellows,
wherein the insulating inner union comprises:
a first nipple that is screw-coupled to a sleeve of the cryocooler inner pipe and a sleeve of the metal inner bellows; and
a second nipple is screw-coupled to the first nipple and connects to the sleeves of both the cryocooler inner pipe and the metal inner bellows.

11. The liquid helium reliquefying circulation apparatus as set forth in claim 9,
wherein both the inner and outer elbow portions are bent at 110 degrees and are formed of metal, ensuring structural integrity and proper alignment,
wherein the outer and inner insertion portions are designed with a double-tube structure,
wherein the outer insertion portion consists of an inner and outer tube,
wherein the inner insertion portion, made from insulating material, includes an inner and outer tube,
wherein the outer tube of the inner insertion portion is coupled to the double-tube structure of the outer insertion portion, thereby sealing the inner insertion portion effectively.

12. The liquid helium reliquefying circulation apparatus as set forth in claim 9, further comprising a return gas line,
wherein the transport pipe assembly incorporates the return gas line inside the outer transport pipe,
wherein the return gas line branches off from the outer insertion portion,
wherein the return gas line facilitates a circulation of helium gas to enhance its efficiency.

13. The liquid helium reliquefying circulation apparatus as set forth in claim 1, further comprising a transport pipe assembly;
the transport pipe assembly comprises inner and outer connection portions that connect the respective ends of the cryocooler inner and outer pipes,
wherein the inner and outer connection portions are designed to be sealed to each other, ensuring no leakage and maintaining the integrity,
wherein the outer connection portion connects the outer transport pipe to an outer intermediate pipe,
wherein the inner connection portion connects the cryocooler outer pipe to an inner intermediate pipe.
